(19) United States
(12) Patent Application Publication
(10) Pub. No.: US 2026/0071348 A1
(43) Pub. Date: Mar. 12, 2026

(54) METHOD FOR CONTROLING PULLING APPARATUS, CONTROL PROGRAM, CONTROL APPARATUS, METHOD FOR PRODUCING SINGLE CRYSTAL SILICON INGOT, AND SINGLE CRYSTAL SILICON INGOT

(71) Applicant: SUMCO Corporation, Tokyo (JP)

(72) Inventors: Mitsuaki HAYASHI, Tokyo (JP); Shuichi OMOTE, Tokyo (JP); Masao SAITOU, Tokyo (JP); Yasuhiro SAITO, Tokyo (JP)

(73) Assignee: SUMCO Corporation, Tokyo (JP)

(21) Appl. No.: 19/133,352

(22) PCT Filed: Aug. 8, 2023
(86) PCT No.: PCT/JP2023/028977

§ 371 Date: May 28, 2025

(30) Foreign Application Priority Data
Nov. 29, 2022 (JP) 2022-190698

(51) Int. Cl. C30B 15/20; C30B 29/06

(52) U.S. Cl. CPC C30B 15/20; C30B 29/06

(57) ABSTRACT

A method for controlling a pulling apparatus for a single crystal silicon ingot includes: obtaining actual results data that relates a measured value of oxygen concentration of a single crystal silicon ingot produced by the pulling apparatus and an operation amount of the pulling apparatus during production, generating an estimation model that estimates the oxygen concentration of a single crystal silicon ingot to be produced by the pulling apparatus based on the actual results data, adjusting the operation amount to be input to the estimation model so that an estimated value of the oxygen concentration of the single crystal silicon ingot by the estimation model becomes target concentration, and determining the adjusted operation amount as the operation amount for producing a single crystal silicon ingot in the next batch of the pulling apparatus.

### TECHNICAL FIELD

This disclosure relates to a method for controlling a pulling apparatus, a control program, a control apparatus, a method for producing a single crystal silicon ingot, and a single crystal silicon ingot.

### BACKGROUND

There are known systems for predicting and controlling the oxygen concentration of a silicon ingot (see, for example, Patent Document 1).

### CITATION LIST

### Patent Literature

PTL 1: JP 2005-162558 A1

### SUMMARY

### Technical Problem

There is a demand for improving the quality of a single crystal silicon ingot.

Therefore, an object of the present disclosure is to provide a method for controlling a pulling apparatus, a control program, a control apparatus, a method for producing a single crystal silicon ingot, and a single crystal silicon ingot, that can improve the quality of a single crystal silicon ingot.

### Solution to Problem

One embodiment of the present disclosure that solves the above problem is as follows.

[1] A method for controlling a pulling apparatus for a single-crystal silicon ingot, including:
obtaining actual results data that relates a measured value of oxygen concentration of a single-crystal silicon ingot produced by the pulling apparatus and an operation amount of the pulling apparatus during production,
generating an estimation model that estimates the oxygen concentration of a single-crystal silicon ingot to be produced by the pulling apparatus based on the actual results data,
adjusting the operation amount to be input to the estimation model so that an estimated value of the oxygen concentration of the single-crystal silicon ingot by the estimation model becomes target concentration, and
determining the adjusted operation amount as the operation amount for producing a single-crystal silicon ingot in the next batch of the pulling apparatus.

[2] The method for controlling a pulling apparatus for a single-crystal silicon ingot as described in [1] above, wherein in generating the estimation model, at least part of the operation amount of the pulling apparatus are selected, and a regression equation with influence degree of the selected operation amount as a coefficient is generated as the estimation model.

[3] The method for controlling a pulling apparatus for a single-crystal silicon ingot as described in [2] above, wherein in generating the estimation model, the operation amount of the pulling apparatus is ranked, and the operation amount of the pulling apparatus is selected based on the ranking.

[4] The method for controlling a pulling apparatus for a single-crystal silicon ingot as described in any one of [1] to [3] above, wherein
in obtaining the actual results data, one or more sets of the actual results data for each of two batches of the pulling apparatus are obtained,
in generating the estimation model, for at least one set of the actual results data out of the one or more sets of the actual results data, differential data between the actual results data of each of the two batches are generated, and a regression equation, that calculates difference in the operation amount of the pulling apparatus based on the differential data of the at least one set, is generated as the estimation model.

[5] The method for controlling a pulling apparatus for a single-crystal silicon ingot as described in any one of [1] to [4] above, wherein in obtaining the actual results data, as the measured value of the oxygen concentration of the single-crystal silicon ingot, the measured value of the oxygen concentration in each of a plurality of segments in a crystal axis direction of the single-crystal silicon ingot is obtained.

[6] The method for controlling a pulling apparatus for a single-crystal silicon ingot as described in [5] above, wherein in generating the estimation model, a segmental estimation model corresponding to each segment in the crystal axis direction of the single-crystal silicon ingot is generated.

[7] The method for controlling a pulling apparatus for a single-crystal silicon ingot as described in [6] above, wherein in adjusting the operation amount, the operation amount when each segment of the single-crystal silicon ingot is pulled up is adjusted based on the segmental estimation model.

[8] The method for controlling a pulling apparatus for a single-crystal silicon ingot as described in any one of [1] to [7] above, wherein in obtaining the actual results data, first measurement data, which is the oxygen concentration of the single-crystal silicon ingot measured using a first method, and second measurement data, which is the oxygen concentration of the single-crystal silicon ingot measured using the second method, are obtained, and data obtained by interpolating the first measurement data with the second measurement data is obtained as the measurement value for the oxygen concentration of the single-crystal silicon ingot.

[9] A control program that causes a processor to execute the method for controlling a pulling apparatus described in any one of [1] to [8] above.

[10] A control apparatus comprises a control section that executes the method for controlling a pulling apparatus described in any one of [1] to [8] above.

[11] A method for producing a single-crystal silicon ingot, including producing the single-crystal silicon ingot using a pulling apparatus controlled by executing the method for controlling a pulling apparatus as described in any one of [1] to [8] above.

[12] A single-crystal silicon ingot produced using a pulling apparatus controlled by executing the method for controlling a pulling apparatus described in any one of [1] to [8].

### Advantageous Effect

According to the method for controlling a pulling apparatus, the control program, the control apparatus, the method for producing a single crystal silicon ingot, and the single crystal silicon ingot, the quality of a single crystal silicon ingot can be improved.

### BRIEF DESCRIPTION OF THE DRAWINGS

In the accompanying drawings:

FIG. 1 is a block diagram illustrating an example of the configuration of a production system in accordance with one embodiment of the present disclosure;

FIG. 2 is a cross-sectional view illustrating an example of the configuration of a pulling apparatus in a cross-section along the pulling axis;

FIG. 3 is a schematic drawing that explains the parts of a single crystal silicon ingot;

FIG. 4 is a flowchart illustrating an example of the procedure for the control method in accordance with one embodiment of the present disclosure;

FIG. 5A provides a histogram of the oxygen concentration in a single crystal silicon ingot produced by setting conditions in the apparatus to be evaluated, using the control method in accordance with a comparative example;

FIG. 5B provides an example of a histogram of the oxygen concentration in a single crystal silicon ingot produced by setting conditions in the apparatus to be evaluated, using the control method in accordance with one embodiment of the present disclosure;

FIG. 6A provides a histogram of the oxygen concentration in a single crystal silicon ingot produced by setting conditions in another apparatus to be evaluated, using the control method in accordance with a comparative example;

FIG. 6B provides an example of a histogram of the oxygen concentration in a single crystal silicon ingot produced by setting conditions in another apparatus to be evaluated, using the control method in accordance with one embodiment of the present disclosure; and

FIG. 7 is a graph illustrating an example of actual data on the oxygen concentration at various points on a single crystal silicon ingot.

### DETAILED DESCRIPTION

### Example of Configuration of Production System 1 for Single Crystal Silicon Ingot

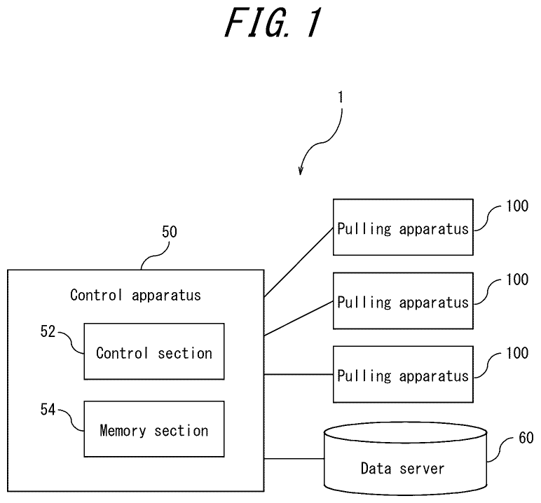

As illustrated in FIG. 1, a production system 1 for a single crystal silicon ingot according to one embodiment of the present disclosure comprises a pulling apparatus for a single crystal silicon ingot, 100, a control apparatus 50, and a data server 60. In the production system 1, the data server 60 stores past production results data of the pulling apparatus 100. The control apparatus 50 determines an operation amount of the pulling apparatus 100 so that the oxygen concentration of a single crystal silicon ingot to be produced by the pulling apparatus 100 is controlled to a target concentration based on the data stored in the data server 60. An example of the configuration of the production system 1 will be described below. The number of the pulling apparatuses 100 in the production system 1 is not limited to three, and may be four or more, or two or less. The number of the control apparatuses 50 or the data server 60 in the production system 1 is not limited to one, and may be two or more.

### Control Device 50

The control apparatus 50 comprises a control section 52 and a memory section 54. The control section 52 may be configured to include at least one processor. The processor can execute programs that realize the various functions of the control section 52. The processor may be implemented as a single integrated circuit. The integrated circuit is also referred to as an IC. The processor may be implemented as a number of communicatively-connected integrated circuits and discrete circuits. The processor may be implemented based on various other known technologies.

The memory section 54 stores various information, such as data obtained from the pulling apparatus 100 or data to be set in the pulling apparatus 100, or programs executed in the control section 52, and others. The memory section 54 may be configured to include an electromagnetic storage medium such as a magnetic disk, or it may be configured to include a memory such as a semiconductor memory or a magnetic memory. The memory section 54 may be configured to include a non-temporary computer-readable medium. The memory section 54 may function as a work memory of the control section 52. At least part of the memory section 54 may be included in the control section 52. At least part of the memory section 54 may be configured as a memory device separate from the control apparatus 50.

The control apparatus 50 may further comprise a communication section that sends and receives data between the pulling apparatus 100 or the data server 60, and the control apparatus 50. The communication section is communicatively connected to the pulling apparatus 100 or the data server 60. The communication section may be communicatively connected to the pulling apparatus 100 or the data server 60 via a network. The communication section may be communicatively connected to the pulling apparatus 100 or the data server 60 by a wired or wireless communication. The communication section may comprise a communication module that connects to a network, or to the pulling apparatus 100 or the data server 60. The communication module may comprise a communication interface such as a LAN (Local Area Network), and others. The communication module may realize communication using various communication methods such as 4G or 5G. The communication method implemented by the communication section is not limited to the above example, and may include various other methods. At least part of the communication section may be included in the control section 52.

The control apparatus 50 may further comprise a display device that outputs visual information such as images, text, or graphics. The display device may be configured to include, for example, an LCD (Liquid Crystal Display), an organic EL (Electro-Luminescence) display or an inorganic EL display, or a PDP (Plasma Display Panel), etc. The display device is not limited to these displays, and may be configured to include various other types of display. The display device may be configured to include light-emitting devices such as LEDs (Light Emitting Diodes) or LDs (Laser Diodes). The display device may be configured to include various other devices in addition to these.

### Data Server 60

As mentioned above, the data server 60 stores the past production results data of the pulling apparatus 100, and outputs the stored data to the control apparatus 50. The data server 60 may be configured to include an electromagnetic storage medium such as a magnetic disk, or may be configured to include a memory such as a semiconductor memory or a magnetic memory. The data server 60 may comprise a processor for storing and outputting data. The data server 60 may comprise a communication section that sends and receives data between the pulling apparatus 100 or the control apparatus 50, and the data server 60. The data server 60 may be configured as a separate unit from the control apparatus 50. At least part of the data server 60 may be configured as an integral part of the control apparatus 50.

### Pulling Apparatus 100

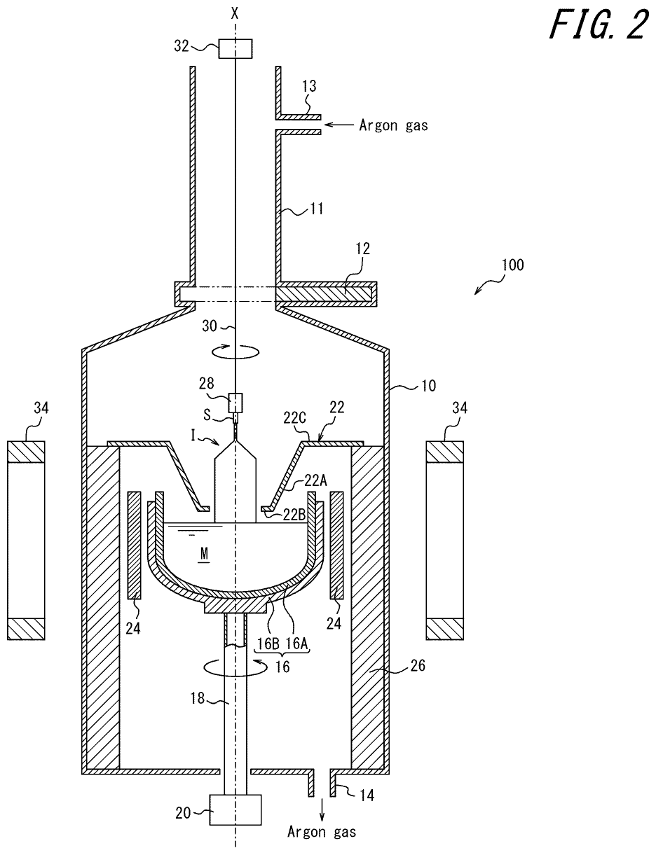

As illustrated in FIG. 2, the pulling apparatus 100 for a single crystal silicon ingot comprises a main chamber 10, a pull chamber 11, a crucible 16, a shaft 18, a shaft drive mechanism 20, a tubular heat shield 22, a tubular heater 24, a tubular insulator 26, a seed chuck 28, a pulling wire 30, a wire lift mechanism 32, and a pair of electromagnets 34.

The main chamber 10 is configured so that the crucible 16 can be accommodated inside thereof. The shape of the main chamber 10 is assumed to be a cylindrical shape with a bottom. The pull chamber 11 has the same central axis as the main chamber 10 and is located above the main chamber 10. The shape of the pull chamber 11 is assumed to be a cylindrical shape with a smaller diameter than the main chamber 10. A gate valve 12 is provided between the main chamber 10 and the pull chamber 11. When the gate valve 12 is opened, the space inside the main chamber 10 and the space inside the pull chamber 11 become mutually connected. When the gate valve 12 is closed, the space inside the main chamber 10 is blocked off from the space inside the pull chamber 11. At the upper part of the pull chamber 11, a gas inlet 13 is provided for introducing inert gases such as argon (Ar) gas into the main chamber 10. In addition, a gas outlet 14 is provided at the bottom part of the main chamber 10 to exhaust the gas inside the main chamber 10 by driving a vacuum pump.

The crucible 16 is disposed in the center of the main chamber 10 and contains silicon melt M. The crucible 16 has a double structure of a quartz crucible 16A and a graphite crucible 16B. The quartz crucible 16A directly supports the silicon melt M on its inner surface. The graphite crucible 16B supports the quartz crucible 16A from outside the quartz crucible 16A. The upper end of the quartz crucible 16A is assumed to be higher than the upper end of the graphite crucible 16B. In other words, the upper end portion of the quartz crucible 16A is assumed to protrude from the upper end of the graphite crucible 16B.

The shaft 18 penetrates the bottom of the main chamber 10 in a vertical direction and supports the crucible 16 at the upper end thereof. The shaft drive mechanism 20 rotates the crucible 16 via the shaft 18 while raises and lowers the same.

The heat shield 22 is provided above the crucible 16 to surround the single crystal silicon ingot I being drawn up from the silicon melt M. Specifically, the heat shield 22 comprises a shield body 22A having an inverted truncated cone shape, an inner flange 22B that extends horizontally from the lower end of the shield body 22A toward the pulling axis X side (inside), and an outer flange 22C that extends horizontally from the upper end portion of the shield body 22A toward the chamber side (outside). The outer flange 22C is fixed to the insulator 26. The heat shield 22 adjusts the amount of high-temperature radiant heat that incidents on the ingot I during growth, from the silicon melt M, the heater 24, and the sidewall of the crucible 16, and also adjusts the amount of heat diffusion near the crystal growth interface. The heat shield 22 is responsible for controlling the temperature gradient in direction of the pulling axis X, at the center and the outer circumference of the single crystal silicon ingot I.

The tubular heater 24 is positioned to surround the crucible 16 within the main chamber 10. The heater 24 is a resistance-heating-type heater made of carbon, and it melts the silicon material that is put into the crucible 16 to form the silicon melt M, and it also heats the formed silicon melt M to maintain the same.

The tubular insulator 26 is provided below the upper end of the heat shield 22, spaced apart from the outer circumferential surface of the heater 24, and along the inner circumferential surface of the main chamber 10. The insulator 26 has the function of providing a heat-retaining effect especially to the area below the heat shield 22 in the main chamber 10, making it easier to maintain the silicon melt M in the crucible 16.

Above the crucible 16, the pulling wire 30, which holds the seed chuck 28, holding the seed crystal S, at its lower end, is arranged on the same axis as the shaft 18, and the wire lift mechanism 32 lifts and lowers the pulling wire 30 while rotating it in the same or opposite direction to the shaft 18 at a predetermined speed.

The pair of electromagnets 34 are located symmetrically with respect to the pulling axis X in the height range that encompasses the crucible 16 outside the main chamber 10. By passing an electric current through the coils of this pair of electromagnets 34, it is possible to generate a horizontal magnetic field that forms a horizontal magnetic field distribution for the silicon melt M. The magnetic field strength can be controlled by the amount of current passing through the coil.

In FIG. 2, the pair of electromagnets 34 that generate a horizontal magnetic field are arranged. Alternatively, electromagnets 34 may be arranged to generate a cusp magnetic field that forms a cusp-shaped magnetic field distribution for the silicon melt M. The arrangement of the electromagnets 34 that generate the cusp magnetic field is done according to standard methods. Also, if a magnetic field is not applied to the silicon melt M during crystal growth, the electromagnet 34 does not need to be arranged.

Each component of the pulling apparatus 100 can be adjusted to a different shape as appropriate according to the specifications of the single crystal silicon ingot to be produced. In other words, the pulling apparatus 100 can be designed with different specifications. The pulling apparatus 100 may be classified into a given groups based on their respective specifications. The pulling apparatus 100 may be classified into groups based on the product specifications or production specifications of the single crystal silicon ingots to be produced by each pulling apparatus 100. The product specifications may include, for example, the crystal diameter, the electrical conductivity type, the electrical resistivity, or the oxygen concentration. The production specifications may include, for example, the pulling speed, the number of crystal rotations, the number of crucible rotations, the flow rate of Ar gas, the internal pressure of furnace, or the strength of magnetic field. In addition, the pulling apparatus 100 for producing a single crystal silicon ingot may be classified into groups based on the specifications of the pulling apparatus 100. The specifications of the pulling apparatus 100 may include, for example, the chamber shape, as well as other factors such as the shape or composition of the carbon components stored in the chamber, the crucible shape, the heater shape, or the presence or absence of a cooling element.

### Production Process for Single Crystal Silicon Ingot Using Pulling Apparatus 100

The pulling apparatus 100 can produce a single crystal silicon ingot by performing the process explained below.

### Raw Material Filling Process

First, silicon raw materials such as polycrystalline silicon nuggets are filled into the quartz crucible 16A located in the main chamber 10. At this time, the gate valve 12 is controlled to be in the open state. The main chamber 10 and the pull chamber 11 are maintained under an inert gas atmosphere such as Ar gas under reduced pressure. In addition, the crucible 16 is located at the bottom of the main chamber 10 so that the silicon raw materials do not come into contact with the heat shield 22.

### Raw Material Melting Process

Next, the silicon raw materials in the crucible 16 are heated by the heater 24 so as to melt. The silicon melt M is formed in the quartz crucible 16A by melting the silicon raw materials. After that, the crucible 16 is raised to a starting position for pulling. This “Raw material melting process” is the period from the point at which the heating by the heater 24 is started to the point at which the ascendant of the crucible 16 is completed.

### Liquid Application Process

Next, the pulling wire 30 descends due to the wire lift mechanism 32, and a seed crystal S comes into contact with the silicon melt M.

### Crystal Growth Process

Next, the single crystal silicon ingot I is pulled up from the silicon melt M. Specifically, the single crystal silicon ingot I is grown below the seed crystal S by pulling the pulling wire 30 upwards while rotating the crucible 16 and the pulling wire 30 in a predetermined direction. As the growth of the ingot I progresses, the amount of the silicon melt M decreases. Therefore, by ascending the crucible 16, the level of the liquid surface is maintained. In this document, the “crystal growth process” is the period from the point at which the pulling wire 30 starts to ascend to the point at which the growth of the ingot I is completed (the point at which the ingot I is separated from the silicon melt M).

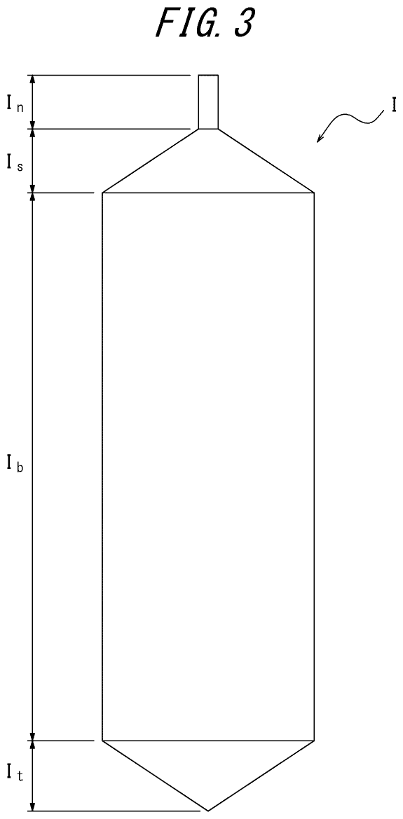

Referring to FIG. 3, in the crystal growth process, a neck portion Iₙ is formed by firstly performing seed-narrowing (necking) using the Dash method to make the single crystal dislocation-free. Next, a shoulder portion Iₛ is formed in which the diameter of the single crystal silicon ingot gradually increases along the crystal growth direction (First process). After that, when the single crystal silicon ingot reaches the desired diameter, the diameter is kept constant and a straight body portion I_{b} is formed (Second process). After growing the straight body portion I_{b} to the specified length, tail thinning is performed to form a tail portion Iₜ, in which the diameter of the single crystal silicon ingot gradually decreases along the crystal growth direction (Third process).

### Ingot Removal Process

Next, the pulled single crystal silicon ingot I is separated from the silicon melt M. The single crystal silicon ingot I ascend inside the main chamber 10 and is accommodated in the pull chamber 11 above the main chamber 10. After the single crystal silicon ingot I is placed in the pull chamber 11, the gate valve 12 is controlled to be in the closed state. The single crystal silicon ingot I is left in the pull chamber 11 with the gate valve 12 closed and is cooled until the removal temperature is 500° C. or below, for example. Finally, the cooled single crystal silicon ingot I is removed from the pull chamber 11. Specifically, while the gate valve 12 is controlled to remain closed, the pull chamber 11 is ascended, descended, and rotated, causing the single crystal silicon ingot I to descend within the pull chamber 11 and be loaded onto the transport cart.

After going through the above process, a single crystal silicon ingot I is produced.

### Example of Operation for Determining Operation Amount of Pulling Apparatus 100

In the production system 1 in accordance with this embodiment, the control apparatus 50 determines the operation amount of the pulling apparatus 100 so that the oxygen concentration of the single crystal silicon ingot to be produced by the pulling apparatus 100 can be controlled to the target concentration, as described above. The following is a specific explanation on an example of the operation of the control apparatus 50.

### Obtaining Actual Results Data

The oxygen concentration of the single crystal silicon ingot produced by the pulling apparatus 100 can be controlled according to the operating amount set for the pulling apparatus 100. The items that can be set as the operating amount of the pulling apparatus 100 to control the oxygen concentration are collectively referred to as pulling information. The pulling information may include, for example, the pulling speed, the number of crystal rotations, the number of crucible rotations, the Ar gas flow rate, the internal pressure of furnace, the heater power, the heater temperature, the melt temperature, the magnetic field strength, the crucible position, the gap, or the time to turn on the heater 24, etc. The melt temperature may include the melt temperature in a dip process, which adjusts the liquid temperature before the crystal growth process. The melt temperature may include the melt temperature in a neck process, which removes the dislocations introduced when a seed crystal comes into contact with the liquid. The melt temperature may include the melt temperature in a shoulder process, which is the initial stage of the crystal growth process and involves increasing the diameter of the crystal.

The oxygen concentration of the single crystal silicon ingot produced by the pulling apparatus 100 can be affected by the specifications of the shape or dimensions of each part of the pulling apparatus 100, or by the amount of time that each part of the pulling apparatus 100 has been used after maintenance. The factors that affect the oxygen concentration but cannot be set as the operation amount of the pulling apparatus 100 are also collectively referred to as material information. The material information may include, for example, the amount of time that parts inside the furnace have been used, or the dimensions and weight of the quartz crucible 16A.

The oxygen concentration of a single crystal silicon ingot to be produced in the next batch by the pulling apparatus 100 is determined based on the pulling information set in the pulling apparatus 100 and the current material information of the pulling apparatus 100. In other words, the pulling information and the material information are factors that affect the oxygen concentration of a single crystal silicon ingot to be produced in the next batch.

The control section 52 of the control apparatus 50 can estimate the oxygen concentration of a single crystal silicon ingot to be produced in the next batch based on the relationship between measurement data of the oxygen concentration of a single crystal silicon ingot produced in a past batch and the pulling and material information at the time of producing the single crystal silicon ingot. The data providing the relationship between the measurement data of the oxygen concentration of a single crystal silicon ingot produced in a past batch and the pulling and material information at the time of producing the single crystal silicon ingot is also referred to as actual results data.

The control section 52 may obtain the actual results data and store it in the data server 60. The control section 52 may obtain the pulling information and the material information which is from the production of a single-crystal silicon ingot in a past batch from the pulling apparatus 100. The control section 52 may obtain the pulling information and the material information which is from the production of a single-crystal silicon ingot in a past batch as information input by the operator operating the pulling apparatus 100. The control section 52 may obtain the measurement data on the oxygen concentration of a single crystal silicon ingot produced in a past batch from a measurement device for the oxygen concentration of a single crystal silicon ingot, or it may obtain the data as information input by the operator who carried out the measurement. The device for measuring the oxygen concentration of a single crystal silicon ingot may be configured as a device that measures the oxygen concentration based on various methods, such as the Full Rod Spectroscopy (FRS) method or the Fourier Transform Infra-red Spectroscopy (FTIR) method, etc. The FRS method is a technique that measures the average oxygen concentration in the radial direction of a single crystal silicon ingot that has been ground into a cylinder by irradiating infrared light from the lateral direction (radial direction) and measuring the absorption intensity. The FRS method can measure the oxygen concentration distribution in a growth axis direction of an ingot by scanning the infrared light that is incident from the lateral direction (radial direction) in the growth axis direction of a single crystal silicon ingot and measuring the absorption intensity of the infrared light at each point in the growth axis direction.

The control section 52 may store data relating the pulling information and the material information when a predetermined single crystal silicon ingot was produced, and the measurement data of the oxygen concentration of the predetermined single crystal silicon ingot, as actual results data, in the data server 60. If the production system 1 comprises a plurality of pulling apparatuses 100, the control section 52 may store the actual results data separately for each pulling apparatus 100. The control section 52 may store the actual results data of the pulling apparatus 100, which are classified by the specifications of the pulling apparatus 100, separately by the specifications of the pulling apparatus 100. The control section 52 may store the actual results data separately by each item of the produced single crystal silicon ingot. The control section 52 may associate the actual results data stored in the data server 60 with labels that identify the pulling apparatus 100, the specifications of the pulling apparatus 100, or the items, etc.

### Generating Estimation Model

The control section 52 of the control apparatus 50 generates a model that estimates the operation amount which is required to control the oxygen concentration of a single crystal silicon ingot to be produced by the pulling apparatus 100 to the target concentration. The model that estimates the operation amount is also referred to as an estimation model.

The control section 52 can extract the factors that have a significant impact on the oxygen concentration of a single crystal silicon ingot by performing multiple regression analysis of the actual results data.

### Obtaining Actual Results Data

The control section 52 obtains actual results data. For example, the control section 52 may specify a pulling apparatus 100 that is to be used to estimate the operation amount for the next batch, and a data server 60 that stores the actual results data for the pulling apparatus 100, or the address within the data server 60, etc.

The control section 52 may specify data to be excluded from the data to be obtained. In other words, the control section 52 may specify data that is not obtained. For example, the control section 52 may specify the actual results data for the first time use of parts such as a B heater, a CCM crucible, a L heater, a lower ring, an outer cylinder, or a spill tray, etc. as data to be excluded and exclude them from the analysis.

### Pre-processing

The control section 52 may perform pre-processing of the actual results data before performing the multiple regression analysis. The control section 52 may execute the following procedure as pre-processing, for example. The control section 52 may calculate the difference between the measurement data of the oxygen concentration of a single crystal silicon ingot produced in a given batch and the measurement data of the oxygen concentration of a single crystal silicon ingot produced in the next batch. The control section 52 may calculate the difference between the pulling and material information when a single crystal silicon ingot was produced in a given batch and the pulling and material information when a single crystal silicon ingot was produced in the next batch. The control section 52 may generate differential data that relates: the difference in the measurement data for the oxygen concentration of the single crystal silicon ingot between the given batch and the next batch; and the difference in the pulling and material information between the given batch and the next batch.

The control section 52 may calculate the difference between any two batches, not just the difference between two consecutive batches, to generate the differential data.

The control section 52 may generate the differential data of two batches for a plurality of combinations. Specifically, the control section 52 may obtain data of two batches for generating the differential data as explained below.

For example, when only one single crystal silicon ingot is pulled from one quartz crucible 16A in the production of one batch, the control section 52 may generate differential data between the measurement data of a single crystal silicon ingot from the first batch and the measurement data of a single crystal silicon ingot from the second batch. The control section 52 may generate differential data between the measurement data of a single crystal silicon ingot from the third batch and the measurement data of a single crystal silicon ingot from the fourth batch. The control section 52 may generate differential data between the measurement data of a single crystal silicon ingot from the fifth batch and the measurement data of a single crystal silicon ingot from the sixth batch. The control section 52 is preferably configured to generate the differential data from the measurement data of single crystal silicon ingots from two consecutive batches.

In the case of the so-called multi-pulling method, in which a plurality of single crystal silicon ingots are pulled from a single quartz crucible 16A in the production of one batch, the control section 52 may generate differential data between the measurement data of each single crystal silicon ingot in a single batch and the measurement data of each single crystal silicon ingot in another batch. For example, if three single crystal silicon ingots are pulled from one quartz crucible 16A in the production of one batch, the control section 52 may generate differential data between the measurement data of the first single crystal silicon ingot from the first batch and the measurement data of the first single crystal silicon ingot from the second batch. The control section 52 may generate differential data between the measurement data of the second single crystal silicon ingot from the first batch and the measurement data of the second single crystal silicon ingot from the second batch. The control section 52 may generate differential data between the measurement data of the third single crystal silicon ingot from the first batch and the measurement data of the third single crystal silicon ingot from the second batch.

Following that, the control section 52 may generate differential data between the measurement data of the first, second and third single crystal silicon ingots from the third batch and the measurement data of the first, second and third single crystal silicon ingots from the fourth batch. The control section 52 may generate differential data between the measurement data of the first, second and third single crystal silicon ingots from the fifth batch and the measurement data of the first, second and third single crystal silicon ingots from the sixth batch. The control section 52 is preferably configured to generate the differential data from the measurement data of single crystal silicon ingots from two consecutive batches.

The above is an example of the case where three single crystal silicon ingots are pulled from one quartz crucible 16A in the production of one batch. The number of silicon ingots that can be pulled from the single quartz crucible 16A is not limited to three, and may be two, or four or more.

The control section 52 may apply the differential data generated for each of the plurality combinations directly to the multivariate analysis described below. The control section 52 may generate differential data, in which the differential data generated for the plurality of combinations are merged for each pulling apparatus 100, as data to be applied to the multivariate analysis described below. The control section 52 may generate differential data, in which the differential data generated for the plurality of combinations are merged for each specification of the pulling apparatus 100, as data to be applied to the multivariate analysis described below. The control section 52 may generate differential data, in which the differential data generated for the plurality of combinations was merged for each item, as data to be applied to the multivariate analysis described below.

The control section 52 may set the change in the operation amount to 0 when the change in the operation amount is less than or equal to the exclusion threshold in the generated differential data. For example, the control section 52 may set the change in the number of crucible rotations in the differential data to 0 when the change in the number of crucible rotations is 0.001 rpm or less. For example, the control section 52 may set the change in the Ar gas flow rate to 0 in the differential data when the change in the Ar gas flow rate is 1 L/min or less. For example, the control section 52 may set the change in the internal pressure of furnace in the differential data to 0 when the change in the internal pressure of furnace is 0.1 torr or less.

The control section 52 may exclude the differential data when the change in the oxygen concentration (ΔOi) in the generated differential data is outside the range. For example, the control section 52 may exclude the differential data for which the absolute value of the change in the oxygen concentration (ΔOi) is 1×10¹⁷ atoms/cm³ or more.

### Modeling

The control section 52 generates an estimation model that estimates the oxygen concentration of a single crystal silicon ingot using the differential data generated by performing the pre-processing on the actual results data. The process of generating an estimation model is also called modeling. The following is an example of how the control section 52 executes modeling. When the production system 1 comprises a plurality of pulling apparatuses 100, the control section 52 may execute modeling for each of the plurality of pulling apparatuses 100 and generate an estimation model to be applied to each of the plurality of pulling apparatuses 100. The control section 52 may divide the plurality of pulling apparatuses 100 into groups, execute modeling for each group, and generate an estimation model to be applied to the pulling apparatuses 100 belonging to each group. The pulling apparatus 100 may be classified into groups based on the product specifications or the production specifications of the single crystal silicon ingot produced by each pulling apparatus 100. The product specifications may include, for example, the crystal diameter, the electrical conductivity type, the electrical resistivity, or the oxygen concentration. The production specifications may include, for example, the pulling speed, the number of crystal rotations, the number of crucible rotations, the flow rate of Ar gas, the internal pressure of furnace, or the strength of the magnetic field. In addition, the pulling apparatus 100 for producing a single crystal silicon ingot may be classified into groups based on the specifications of the pulling apparatus 100. The specifications of the pulling apparatus 100 may include, for example, the chamber shape, as well as other factors such as the shape or composition of the carbon components stored in the chamber, the crucible shape, the heater shape, or the presence or absence of a cooling element.

The control section 52 performs multivariate analysis on the differential data or the merged differential data that has been generated by performing pre-processing on the actual results data. When the control section 52 has not performed any pre-processing on the actual results data, it performs multivariate analysis on the actual results data. In this embodiment, the control section 52 executes a multiple regression analysis as the multivariate analysis. The control section 52 may execute various other methods as the multivariate analysis, not limited to the multiple regression analysis.

The control section 52 calculates the degree of influence of explanatory variables on an objective variable by performing the multiple regression analysis on the differential data, the merged differential data, or the actual results data, and generates a linear or non-linear regression equation with the degree of influence as the coefficient. The objective variable is the oxygen concentration in a single crystal silicon ingot. The explanatory variables may include each item of the pulling information or the material information, for example, the Ar gas flow rate, the internal pressure of furnace, or the number of crucible rotations, etc. The degree of influence can be expressed as a ratio of the change in the value of the objective variable to the change in the value of the explanatory variable.

The control section 52 may generate a regression equation using all of the items of the pulling information and the material information as the explanatory variables. The control section 52 may generate a regression equation by selecting the explanatory variables from among the items of the pulling information and the material information. The control section 52 may preferably generate a regression equation by selecting at least three explanatory variables. The control section 52 may, as a criterion for selecting the explanatory variables, assign priority to each explanatory variable based on the degree of influence of each explanatory variable obtained by performing the multiple regression analysis, and select the explanatory variables in order of priority, for example. The control section 52 may assign a high rank to the explanatory variables that can be controlled as the operation amount of the pulling apparatus 100. The control section 52 may assign priorities to each explanatory variable based on information input by the process engineer, operator, or manager of the pulling apparatus 100. In other words, the priority of the explanatory variables may be assigned based on the knowledge of the process engineer, operator, or manager of the pulling apparatus 100. In addition, the priority of the explanatory variables may be assigned by taking into account the past experience of the process engineer, operator, or manager of the pulling apparatus 100. Due to various restrictions in the actual production of the single crystal silicon ingot, the range in which the values of the explanatory variables change is limited. The priority of the explanatory variables may be assigned by considering the range over which the value of the explanatory variable can change. For example, the wider the range over which the value of the explanatory variable can change, the higher the rank assigned to that explanatory variable.

The control section 52 uses the regression equation generated with the selected explanatory variables to estimate the oxygen concentration of a given batch contained in the actual results data. If the difference between the estimated value of the oxygen concentration of a given batch and the measured value of the oxygen concentration of the given batch is less than the judgment threshold, the control section 52 determines that the generated regression equation is valid and decides to use the generated regression equation as the estimation model. In other words, the control section 52 decides to use the regression equation generated using the oxygen concentration of a single crystal silicon ingot as the objective variable, as the estimation model for estimating the oxygen concentration of a single crystal silicon ingot.

If the difference between the estimated value of the oxygen concentration for a given batch and the measured value of the oxygen concentration for the given batch is greater than or equal to the judgment threshold, the control section 52 changes at least some of the explanatory variables to other items and re-creates a regression equation. The control section 52 may change the explanatory variables based on the ranking attached to the explanatory variables, or it may change the explanatory variables based on information input by the process engineer of the pulling apparatus 100, etc. The control section 52 repeats changing the explanatory variables and generating a regression equation until the difference between the estimated value of the oxygen concentration of a given batch calculated using the generated regression equation and the measured value of the oxygen concentration of the given batch becomes less than the judgment threshold.

The degree of influence of the explanatory variable of the pulling apparatus 100 on the oxygen concentration can differ for each furnace of the pulling apparatus 100. In addition, the degree of influence can differ for each type of the heat shield 22. The control section 52 may change the order of the explanatory variables for each furnace or for each type of the heat shield 22. In this way, the accuracy of the parameters of the estimation model can be improved.

### Summary of Generation of Estimation Model

As described above, the control section 52 can generate an estimation model. By verifying the generated regression equation with actual results data, the accuracy of the estimated oxygen concentration using the estimation model can be improved. In addition, the explanatory variables are selected based on the information input by the process engineers of the pulling apparatus 100, therefore, the knowledge of the process engineers can be reflected in the estimation model. By using an estimation model reflecting knowledge, it becomes possible to obtain the same estimation results no matter who operates it. In other words, the subjectivity of the estimation can be reduced.

The control section 52 may obtain one or more sets of actual results data for each of two batches of the pulling apparatus 100. The control section 52 may generate the differential data of the actual results data of each of two batches for at least one set of actual results data out of one or more sets of actual results data. The control section 52 may generate a regression equation as an estimation model that calculates the difference in the operation amount of the pulling apparatus 100 based on at least one set of the generated differential data. The estimation accuracy can be improved by generating a regression equation based on the differential data calculated for a plurality of combinations of two batches.

The oxygen concentration in a single crystal silicon ingot can vary from place to place. For example, the oxygen concentration in the shoulder portion Iₛ, the oxygen concentration in the straight body portion I_{b}, and the oxygen concentration in the tail portion Iₜ can be different from each other. In addition, even within the straight body portion (I_{b}), the oxygen concentration on the side closer to the shoulder portion (Iₛ) can differ from the oxygen concentration on the side closer to the tail portion (Iₜ). In addition, the oxygen concentration in each part in the crystal axis direction of the straight body I_{b} can vary depending on the distance from the shoulder portion Iₛ. Each part in the crystal axis direction of the straight body portion I_{b} may be specified by the distance from the boundary between the shoulder portion Iₛ and the straight body portion I_{b}. The oxygen concentration in each part of a single crystal silicon ingot can be controlled according to the operation amount during pulling the each part.

The control section 52 may classify the straight portion I_{b} of the single crystal silicon ingot into a plurality of segments in the crystal axis direction based on the distance from the boundary between the shoulder portion Iₛ and the straight body portion I_{b}. The control section 52 may generate a model that estimates the operation amount when each segment is raised in order to control the oxygen concentration of each segment to the target concentration. In other words, the control section 52 may generate an estimation model corresponding to each segment. In this case, the control section 52 may obtain the actual results data or the differential data and measured oxygen concentration value for each segment. The estimation model corresponding to each segment is also called a segmental estimation model.

### Estimation of Operation Amount for Next Batch

The control section 52 uses the determined estimation model to estimate the oxygen concentration of a single crystal silicon ingot to be produced in the next batch of the pulling apparatus 100. The control section 52 adjusts the values of the explanatory variables contained in the estimation model so that the estimated oxygen concentration of the single crystal silicon ingot to be produced in the next batch becomes the target concentration. The target concentration may be, for example, the center value of the oxygen concentration standard for an item to be produced in the next batch. The control section 52 determines the value of the explanatory variable, which has been adjusted so that the estimated oxygen concentration becomes the target concentration, as a recommended value of the operation amount for the next batch of the pulling apparatus 100. For example, if the control section 52 selects the Ar gas flow rate, the internal pressure of furnace, and the number of crucible rotation as the explanatory variables, it may use the estimation model to determine the recommended values for the Ar gas flow rate, the internal pressure of furnace, and the number of crucible rotation for the next batch of the pulling apparatus 100.

The control section 52 may determine the recommended value for the operation amount so that the estimated oxygen concentration in each segment in the crystal axis direction of the straight body portion I_{b} of the single crystal silicon ingot becomes the target concentration. The operation amount of the pulling apparatus 100 can be changed while pulling up the single crystal silicon ingot. The control section 52 may adjust the operation amount when each segment in the crystal axis direction of the single crystal silicon ingot is being pulled up based on the segmented estimation model, and determine the estimated value of the operation amount for each segment.

The control section 52 may notify the operator of the pulling apparatus 100 of the recommended value for the determined operation amount. In this case, the operator may set the operation amount of the pulling apparatus 100 to the recommended value. The control section 52 may output the recommended value for the determined operation amount to the pulling apparatus 100 and set the recommended value as the operation amount as is.

### Example of Procedure on Control Method

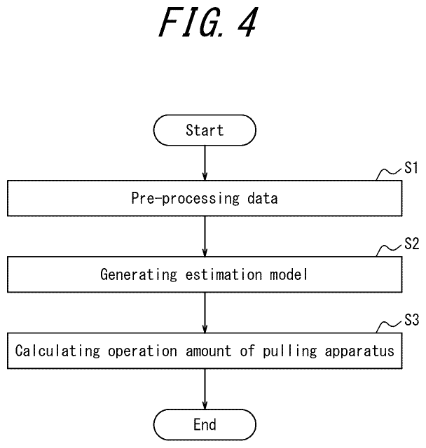

The control section 52 may execute a control method that includes the procedure of the flowchart illustrated in FIG. 4 in order to estimate the operation amount of the pulling apparatus 100. The control method may be implemented as a control program that is executed by the control section 52.

The control section 52 executes pre-processing of the data (step S1). The control section 52 generates an estimation model for estimating the appropriate operation amount to be set for the pulling apparatus 100 based on the preprocessed data (step S2). The control section 52 calculates the operation amount of the pulling apparatus 100 using the estimation model so that the oxygen concentration of the single crystal silicon ingot to be produced by the pulling apparatus 100 can be controlled to the target concentration (step S3). After executing the procedure in Step S3, the control section 52 may end execution of the procedure in the flowchart in FIG. 4.

The control section 52 may output the operation amount calculated in the procedure of step S3 to the pulling apparatus 100 to set the operation amount in the pulling apparatus 100, and may begin producing a single crystal silicon ingot using the pulling apparatus 100. The control section 52 may notify the operator of the pulling apparatus 100 of the operation amount calculated in the procedure of step S3. The operator may set the notified operation amount to the pulling apparatus 100 and begin producing a single crystal silicon ingot using the pulling apparatus 100.

### Summary

As described above, in the production system 1 in accordance with one embodiment of the present disclosure, the control section 52 of the control apparatus 50 can generate an estimation model and use the estimation model to estimate the operation amount for the next batch in the pulling apparatus 100. In this way, the estimation of the operation amount of the pulling apparatus 100 can be systematized. By systemizing the estimation of the operation amount, it is easy to increase the number of items to be considered as actual parameters that affect the oxygen concentration. In addition, the degree of subjectivity can be reduced. By increasing the number of items to be considered or reducing subjectivity, the oxygen concentration can be controlled with high precision. In addition, it is possible to reduce the variation in the oxygen concentration and improve process capability. As a result, the quality of a single crystal silicon ingot produced by the pulling apparatus 100 can be improved.

As a comparison, in a method for producing silicon single crystals using the Czochralski method (hereafter, the CZ method), the parameters for the next batch are predicted based on past pulling results (the oxygen concentration, the material information, and the pulling information) and on a setting criteria and empirical rules of humans. In this case, there may be individual differences in the parameter prediction. In addition, it can be complicated to manage the factors that affect oxygen concentration. As a result, the variation in the oxygen concentration may increase.

On the other hand, in the production system 1 in accordance with one embodiment of the present disclosure, the control section 52 of the control apparatus 50 can optimize the pulling parameter values for the next batch using the estimation model predicted by multiple regression analysis. In addition, by systemizing the determination of the pulling parameter values, individual differences can be eliminated. Furthermore, factors that affect the oxygen concentration can be easily managed. As a result, the variation in the oxygen concentration can be reduced.

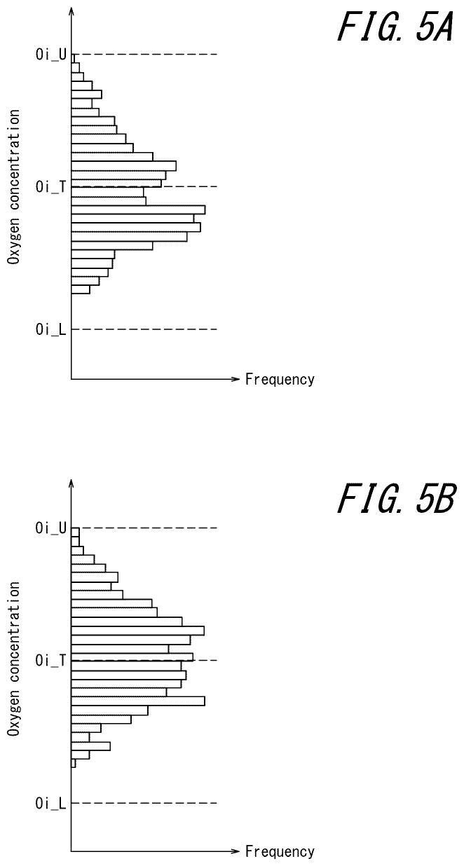

Here, when a single crystal silicon ingot was produced by determining the operation amount of the first apparatus to be evaluated using the method of the comparative example, the oxygen concentration of the single crystal silicon ingot produced using the first apparatus to be evaluated was distributed as provided in FIG. 5A as a histogram. The vertical axis in FIG. 5A indicates the oxygen concentration categories. The “Oi_T” on the vertical axis indicates the target concentration. The “Oi_U” on the vertical axis indicates the upper limit of standard or the upper limit of control for the oxygen concentration. The “Oi_L” on the vertical axis indicates the lower limit of standard or the lower limit of control for the oxygen concentration. The horizontal axis indicates the frequency of each categories. The calculated process capability index (Cpk) for the distribution of the oxygen concentration in FIG. 5A was 0.93.

On the other hand, when a single crystal silicon ingot was produced by determining the operation amount of the first apparatus to be evaluated using the control method in accordance with this embodiment, the oxygen concentration of the single crystal silicon ingot produced using the first apparatus to be evaluated was distributed as provided in FIG. 5B as a histogram. The vertical and horizontal axes in FIG. 5B are the same as those in FIG. 5A. The calculated process capability index (Cpk) for the distribution of the oxygen concentration in FIG. 5B was 0.97.

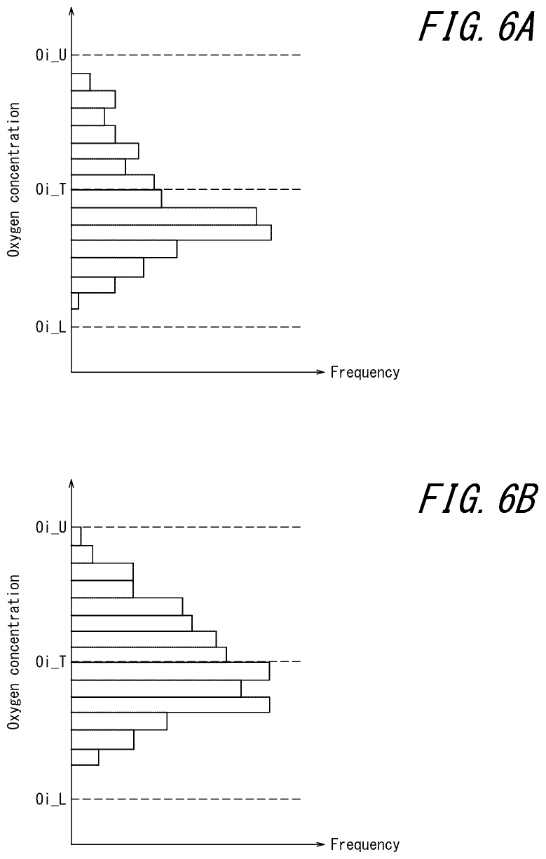

Also, when a single crystal silicon ingot was produced by determining the operation amount of the second apparatus to be evaluated using the method of the comparative example, the oxygen concentration of the single crystal silicon ingot produced using the second apparatus to be evaluated was distributed as provided in FIG. 6A as a histogram. The vertical and horizontal axes in FIG. 6A are the same as those in FIG. 5A. The calculated process capability index (Cpk) for the distribution of the oxygen concentration in FIG. 6A was 0.83.

On the other hand, when a single crystal silicon ingot was produced by determining the operation amount of the second apparatus to be evaluated using the control method in accordance with this embodiment, the oxygen concentration of the single crystal silicon ingot produced using the second apparatus to be evaluated was distributed as provided in FIG. 6B as a histogram. The vertical and horizontal axes in FIG. 6B are the same as those in FIG. 5A. The calculated process capability index (Cpk) for the distribution of the oxygen concentration in FIG. 6B was 0.94.

As explained above, when determining the operation amount of the apparatus to be evaluated using the control method in accordance with this embodiment, the process capability index (Cpk) of the oxygen concentration of the single crystal silicon ingot produced by the apparatus to be evaluated can be improved compared to when the operation amount is predicted based on the empirical rules of humans, as described as a comparative example. In other words, according to the control method in accordance with this embodiment, the quality of the single crystal silicon ingot produced by the pulling apparatus 100 can be improved.

### Other Embodiments

The following describes other embodiments.

### Interpolation of Oxygen Concentration

The oxygen concentration of a single crystal silicon ingot can be measured at short intervals without cutting the ingot using the Full Rod Spectroscopy (FRS) method. The FRS method is a technique that measures the average oxygen concentration in the radial direction of a single crystal silicon ingot that has been ground into a cylinder by irradiating infrared light from the lateral direction (radial direction) and measuring the absorption intensity. The FRS method can measure the oxygen concentration distribution in the growth axis direction of a single crystal silicon ingot by scanning the infrared light that is incident from the lateral direction (diameter direction) in the growth axis direction of the ingot and measuring the absorption intensity of the infrared light at each point in the growth axis direction. In addition, the oxygen concentration of a single crystal silicon ingot can be measured with high accuracy using samples cut from the single crystal silicon ingot using Fourier Transform Infra-red Spectroscopy (FTIR). The oxygen concentration of a single crystal silicon ingot can be measured using various methods, not just the FRS or FTIR methods illustrated here.

The control section 52 may obtain data measured at narrow intervals using the FRS method and data measured at wide intervals with high precision using the FTIR method, as data on the oxygen concentration of a single crystal silicon ingot produced in the past as actual results data. The control section 52 may correct the data measured using the FRS method, using data measured with high precision using the FTIR method. In other words, the control section 52 can generate data on the oxygen concentration measured at narrow intervals with high accuracy, by interpolating data on the oxygen concentration measured at wide intervals with high accuracy using the FTIR method based on the trend of data on the oxygen concentration measured at narrow intervals using the FRS method.

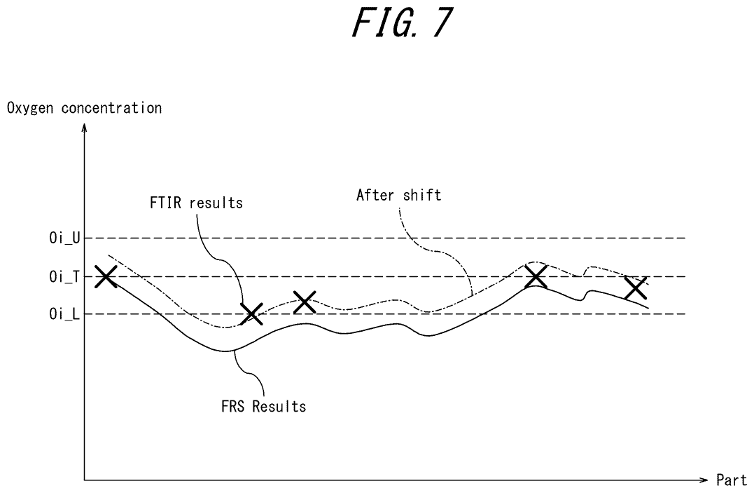

For example, as illustrated in FIG. 7, the control section 52 obtains measured values of the oxygen concentration at each part of the single crystal silicon ingot measured using the FRS method and the FTIR method. The horizontal axis of the graph in FIG. 7 indicates the position of the single crystal silicon ingot in the crystal axis direction. The vertical axis indicates the oxygen concentration. The “Oi_T” on the vertical axis indicates the target concentration. The “Oi_U” on the vertical axis indicates the upper limit of standard or the upper limit of control for the oxygen concentration. The “Oi_L” on the vertical axis indicates the lower limit of standard or the lower limit of control for the oxygen concentration. The values of the oxygen concentration measured using the FRS method are indicated by a solid line as “FRS results”. The values of the oxygen concentration measured using the FTIR method is indicated by X marks, which is provided as “FTIR results”.

The control section 52 can match the measured values of the oxygen concentration in each part from the FRS results to the measured values of the oxygen concentration in each part from the FTIR results, while maintaining the trend of the measured values for the oxygen concentration in each part from the FTS results. Specifically, the control section 52 may shift the graph of the measured oxygen concentration from the FRS results to the graph of the measured oxygen concentration from the FTIR results. The oxygen concentration after the shift is indicated by the dash-dotted line. The control section 52 may generate actual results data by relating the shifted oxygen concentration to the pulling information and the material information. In this way, the accuracy of the estimation model can be improved.

The method for measuring the oxygen concentration of a single crystal silicon ingot by applying the FRS method is also referred to as the first method. The method for measuring the oxygen concentration in a single crystal silicon ingot by applying the FTIR method is also known as the second method. The control section 52 may obtain the first measurement data, which is the oxygen concentration of the single crystal silicon ingot measured by the first method, and the second measurement data, which is the oxygen concentration of the single crystal silicon ingot measured by the second method. The control section 52 may interpolate the first measurement data with the second measurement data, and obtain the interpolated data as the measurement value of the oxygen concentration of the single crystal silicon ingot. Various other measurement methods may be applied as the first and second methods.

### Method for Producing Single Crystal Silicon Ingot and Single Crystal Silicon Ingot

In the production system 1 in accordance with this embodiment, a single crystal silicon ingot is produced by the pulling apparatus 100, which is controlled by the control apparatus 50. Accordingly, a method for producing a single crystal silicon ingot is achieved, which includes pulling a single crystal silicon ingot with the pulling apparatus 100 controlled by the control apparatus 50 executing the control method. In addition, a single crystal silicon ingot produced by the pulling apparatus 100 controlled by the control apparatus 50 executing the control method is achieved.

### Example of Configuration of Apparatus

In the production system 1, the control apparatus 50 may be included in part of the pulling apparatus 100. The control apparatus 50 and the pulling apparatus 100 may be configured as separate units. The data server 60 may be included in part of the control apparatus 50 or the pulling apparatus 100. The data server 60 may be configured separately from the control apparatus 50 and the pulling apparatus 100.

The embodiments of the present disclosure have been described based on various drawings and examples, but it should be noted that a person skilled in the art would be able to make various modifications or alterations based on the present disclosure. Therefore, it should be noted that these variations and modifications are included within the scope of the present disclosure. For example, the functions contained in each component or each step, etc. can be rearranged so that they do not contradict logically, and it is possible to combine multiple components or steps, etc. into one or split them into multiple components or steps, etc. Although the embodiments in accordance with this disclosure have mainly been explained in terms of the apparatus, the embodiments according to this disclosure can also be realized as methods that include steps executed by each component of the apparatus. The embodiments in accordance with the present disclosure can also be realized as methods, programs, or storage media that record programs, which are executed by the processor provided in the apparatus. It is to be understood that these are also encompassed within the scope of the present disclosure.

The graphs included in this disclosure are schematic. The scales and the like do not necessarily correspond to the actual ones.

### Industrial Applicability

According to the embodiment of this disclosure, the quality of a single crystal silicon ingot can be improved.

### Reference Signs List

1 Production system

50 Monitoring apparatus (52: Control section, 54: Memory section)

60 Data server

100 Pulling apparatus (10: Main chamber, 11: Pull chamber, 12: Gate valve, 13: Gas inlet, 14: Gas outlet, 16: Crucible, 16A: Quartz crucible, 16B: Graphite crucible, 18: Shaft, 20: Shaft drive mechanism, 22: Heat shield, 22A: Shield body, 22B: Inner flange, 22C: Outer flange, 24: Heater, 26: Insulator, 28: Seed chuck, 30: Pulling wire, 32: Wire lift mechanism, 34: Electromagnet, S: Seed crystal, M: Silicon melt, X: Pulling axis)

I Single crystal silicon ingot (Iₙ: Neck portion, Iₛ: Shoulder portion, I_{b}: Straight body portion, I_{b1}: First straight body portion, I_{b2}: Second straight body portion, Iₜ: Tail portion)

1. A method for controlling a pulling apparatus for a single crystal silicon ingot, including:
obtaining actual results data that relates a measured value of oxygen concentration of a single crystal silicon ingot produced by the pulling apparatus and an operation amount of the pulling apparatus during production,
generating an estimation model that estimates the oxygen concentration of a single crystal silicon ingot to be produced by the pulling apparatus based on the actual results data,
adjusting the operation amount to be input to the estimation model so that an estimated value of the oxygen concentration of the single crystal silicon ingot by the estimation model becomes target concentration, and
determining the adjusted operation amount as the operation amount for producing a single crystal silicon ingot in the next batch of the pulling apparatus.

2. The method for controlling a pulling apparatus for a single crystal silicon ingot as described in claim 1, wherein in generating the estimation model, at least part of the operation amount of the pulling apparatus are selected, and a regression equation with influence degree of the selected operation amount as a coefficient is generated as the estimation model.

3. The method for controlling a pulling apparatus for a single crystal silicon ingot as described in claim 2, wherein in generating the estimation model, the operation amount of the pulling apparatus is ranked, and the operation amount of the pulling apparatus is selected based on the ranking.

4. The method for controlling a pulling apparatus for a single crystal silicon ingot as described in claim 1, wherein
in obtaining the actual results data, one or more sets of the actual results data for each of two batches of the pulling apparatus are obtained,
in generating the estimation model, for at least one set of the actual results data out of the one or more sets of the actual results data, differential data between the actual results data of each of the two batches are generated, and a regression equation, that calculates difference in the operation amount of the pulling apparatus based on the differential data of the at least one set, is generated as the estimation model.

5. The method for controlling a pulling apparatus for a single crystal silicon ingot as described in claim 1, wherein in obtaining the actual results data, as the measured value of the oxygen concentration of the single crystal silicon ingot, the measured value of the oxygen concentration in each of a plurality of segments in a crystal axis direction of the single crystal silicon ingot is obtained.

6. The method for controlling a pulling apparatus for a single crystal silicon ingot as described in claim 5, wherein in generating the estimation model, a segmental estimation model corresponding to each segment in the crystal axis direction of the single crystal silicon ingot is generated.

7. The method for controlling a pulling apparatus for a single crystal silicon ingot as described in claim 6, wherein in adjusting the operation amount, the operation amount when each segment of the single crystal silicon ingot is pulled up is adjusted based on the segmental estimation model.

8. The method for controlling a pulling apparatus for a single crystal silicon ingot as described in claim 1, wherein in obtaining the actual results data, first measurement data, which is the oxygen concentration of the single crystal silicon ingot measured using a first method, and second measurement data, which is the oxygen concentration of the single crystal silicon ingot measured using the second method, are obtained, and data obtained by interpolating the first measurement data with the second measurement data is obtained as the measurement value for the oxygen concentration of the single crystal silicon ingot.

9. A non-transitory computer readable medium storing a control program that causes a processor to execute the method for controlling a pulling apparatus described in claim 1.

10. A control apparatus comprises a control section that executes the method for controlling a pulling apparatus described in claim 1.

11. A method for producing a single crystal silicon ingot, including producing the single crystal silicon ingot using a pulling apparatus controlled by executing the method for controlling a pulling apparatus as described in claim 1.

12. A single crystal silicon ingot produced using a pulling apparatus controlled by executing the method for controlling a pulling apparatus described in any claim 1.
